(19) United States
(12) Patent Application Publication
(10) Pub. No.: US 2021/0026999 A1
(43) Pub. Date: Jan. 28, 2021

(54) METHOD AND DEVICE FOR VALIDATING A SIMULATION OF A TECHNICAL SYSTEM

(71) Applicant: Robert Bosch GmbH, Stuttgart (DE)

(72) Inventor: Stephan Rhode, Karlsruhe (DE)

(21) Appl. No.: 16/894,204

(22) Filed: Jun. 5, 2020

(30) Foreign Application Priority Data
Jul. 25, 2019 (DE) 102019211076.2

(51) Int. Cl. G06F 30/20; G05B 17/02

(52) U.S. Cl. CPC G06F 30/20; B60W 60/00; G05B 17/02

(57) ABSTRACT

A method for validating a simulation of a technical system. The method including the following features: for combinations of measurement series obtained on the system and results of the simulation corresponding to the measurement series, a specified validation metric is computed in each case; and the simulation is validated on the basis of the computed validation metrics.

### CROSS REFERENCE

The present application claims the benefit under 35 U.S.C. § 119 of German Patent Application No. DE 102019211076.2 filed on Jul. 25, 2019, which is expressly incorporated herein by reference in its entirety.

### FIELD

The present invention relates to a method for validating a simulation of a technical system. The present invention also relates to a corresponding device, a corresponding computer program, as well as to a corresponding storage medium.

### BACKGROUND INFORMATION

In software engineering, the use of models for automating test activities and for generating test artifacts in the test process is summarized under the generic term model-based testing, MBT. It is conventional, for example, to generate test cases from models which describe the nominal behavior of the system to be tested.

Embedded systems, in particular, are dependent on coherent input signals from sensors. They, in turn, stimulate the environment thereof by transmitting output signals to the most diverse actuators. Therefore, in the course of the verification and upstream development phases of such a system, the model thereof (model in the loop, MiL), software (software in the loop, SiL), processor (processor in the loop, PiL) or total hardware (hardware in the loop, HiL) is simulated in a control loop, together with a model of the environment. In vehicle technology, simulators, which are based on this principle and are used for testing electronic control units, are sometimes referred to as component, module or integration testers, depending on the test phase and test object.

German Patent Application No. DE 10303489 A1 describes such a method for testing software of a control unit of a vehicle, where a test system at least partially simulates a controlled system that is controllable by the control unit, by output signals, which are transmitted to first hardware modules via a first connection, being generated by the control unit, and signals from second hardware modules being transmitted as input signals to the control unit via a second connection, the output signals being provided as first control values in the software and being additionally transmitted to the test system via a communication interface in real time with respect to the controlled system.

Simulations of this kind are common in various fields of technology and are used, for example, to test the suitability of embedded systems in power tools, motor control units for drive systems, steering systems and braking systems or even in autonomous vehicles in the early stages of the development thereof. Nevertheless, the results of related art simulation models are only included to a limited extent in release decisions due to a lack of confidence in the reliability thereof.

### SUMMARY

The present invention provides a method for validating a simulation of a technical system, a corresponding device, a corresponding computer program, as well as a corresponding storage medium.

The present invention is based on the realization that validating time signals from simulation models is a question of comparing the output of the simulation model and measured values from tests. Here, the selected simulation signals or measurement signals describe a quantity of interest, QOI which may be scalar or be available in a time series.

An example embodiment of the present invention takes into account the fact that validating a simulation on the basis of a measurement is the simplest case of a validation. To this end, either two scalars or two time series are compared to one another. In practice, however, to minimize statistical uncertainties in the validation, for the most part, a comparison of a plurality of retests with a plurality of repeated simulations is sought. This statistical comparison, which may be performed using what are generally referred to as trust or confidence intervals, for example, is customary in the case of scalars. Moreover, for scalar QOIs, the validation was provided using what are generally referred to as probability boxes, p-boxes. Here, it is a comparison of two cumulative distribution functions, CDFs.

Finally, the example method of the present invention described herein is based on the insight that the validation of a time series differs from that of a scalar by the use of a validation metric. A validation metric is a mathematical function that maps two time series onto a scalar that is likewise referred to as a validation metric. The most well-known example is the mean squared error, MSE, defined as follows:

$$\frac{1}{n} {\sum }_{i = 1}^{n} {( {Y}_{i} - {\hat{Y}}_{i} )}^{2}$$

The comparison of time series of a simulation with a measurement seems, in fact, to be available in the related art, not, however, a method for comparing a plurality of measurements and simulations using a validation metric. Conventional is merely directly comparing a plurality of time series from simulation and measurements using confidence bands. However, this statistical method has the disadvantage, for example, that simulations having excessively high frequency components reside within a confidence band of the measurements and may thus be incorrectly classified as valid. FIG. 1 shows such a case.

This disadvantage is eliminated by the use in accordance with the present invention of a validation metric, which generically permits a comparison of properties, such as phase errors or magnitude errors of time series, for example.

An advantage of the example embodiment of the present invention resides in attributing the validation problem to scalar methods based on confidence interval, p-box or CDF. To this end, the time signals are not directly compared, but a validation metric is initially applied. In comparison to conventional methods, the metric is not only computed for the static pairing of a single simulation with a measurement, but for all combinations of existing measurements and simulation results.

The measures described herein make possible advantageous embodiments of the basic embodiment of the present invention, and improvements thereto. Thus, a use may be provided in the field of automated driving and of other automated systems, for example, of robotics. In these fields of application, in particular, an inventive verification and validation of embedded systems may effectively enhance the functional reliability thereof.

Another aspect of the present invention may provide for the direct use of simulations for uncertainty quantification, UQ, for instance, in contrast to related art deterministic simulations.

### BRIEF DESCRIPTION OF THE DRAWINGS

Exemplary embodiments of the present invention are illustrated in the drawing and explained in greater detail below.

FIG. 1 shows a simulation that is incorrectly classified as valid due to excessively high frequency components.

FIG. 2 shows the flow chart of a method in accordance with a first specific embodiment of the present invention.

FIG. 3 shows a first matrix that is defined within the scope of the method according to the present invention.

FIG. 4 shows a second matrix that is defined within the scope of the method according to the present invention.

FIG. 5 shows a vector that is defined within the scope of the method according to the present invention.

FIG. 6 shows the validation metrics as a cumulative distribution function in accordance with the present invention.

FIG. 7 illustrates validation metrics as a confidence interval in accordance with the present invention.

FIG. 8 schematically shows a processing station in accordance with a second specific embodiment.

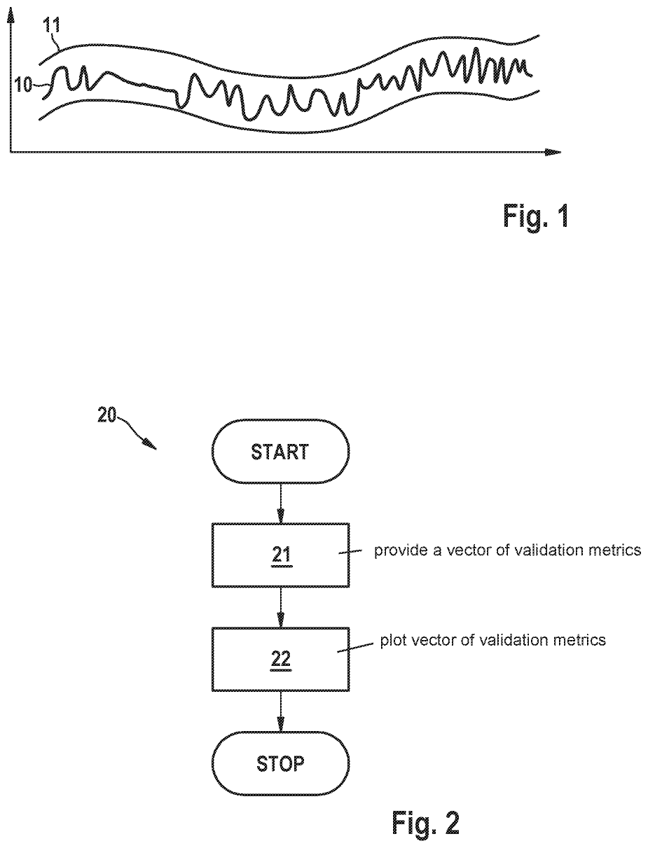

### DETAILED DESCRIPTION OF EXAMPLE EMBODIMENTS

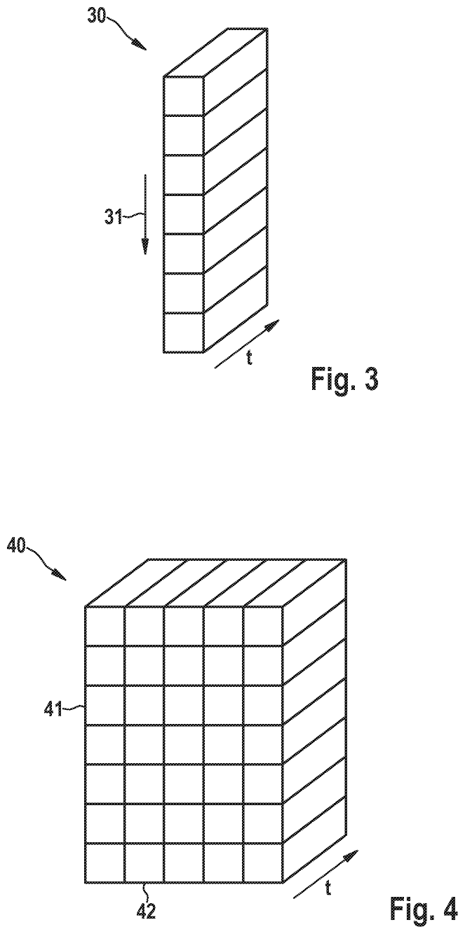

FIG. 2 illustrates the basic steps of an example method (20) according to the present invention. In a first step (process 21), all repetitive measurements are collected in a first matrix (30—FIG. 3), whose rows (31) each represent an index of the repetitive measurement, and the depth dimension represents the stored time series.

A second matrix (40) sketched in FIG. 4 represents simulation results from UQ simulations. The rows (41) thereof correspond to aleatoric uncertainties and the columns (42) thereof to epistemic uncertainties, while the depth dimension again represents the stored time series itself.

An exemplary application programming interface, API may include the following class definition: “that StatisticSignalMetric( . . . , measurements, simulation, signal comparator).” The “measurements” and “simulation” arguments represent here the above described matrices of measurements, respectively simulations. Finally, the third argument, “signal_comparator,” represents the function of the validation metric, which may be selected from a plurality of relevant metrics.

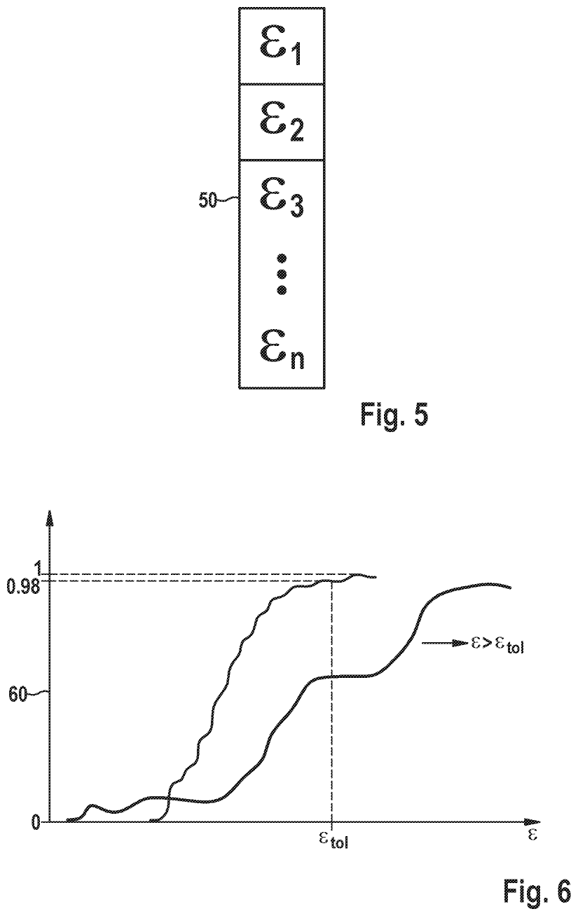

This first step (21) of method (20) provides a vector (50—FIG. 5) of scalar validation metrics, whose dimension corresponds to the number of possible paired combinations of the measurements, on the one hand, and of the simulations, on the other hand.

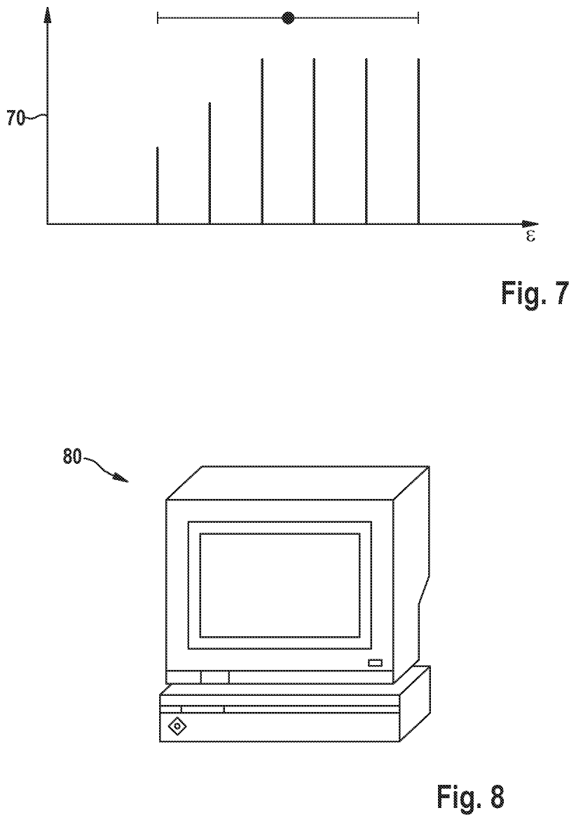

In a second step (process 22—FIG. 2), vector (50) of the validation metrics is plotted as a confidence interval (60—FIG. 7) or CDF (70—FIG. 6). Specified here is an upper limit (εₜₒₗ) for the permissible range of values of validation metric (ε) that is generally derived from project-specific requirements. From confidence interval plot (60), it is possible to read off the variability of the validation metric (ε) and check whether confidence interval (60) is below limit (εₜₒₗ). Thus, in comparison to the conventional confidence band method, the robustness of the validation may be additionally evaluated.

In CDF plot (70), limit (εₜₒₗ) may be marked on the x-axis, and the probability of limit (εₜₒₗ) being observed may be read off of the y-axis. Here as well, the shape of CDF (70) shows how robust the validation is.

This method (20) may be implemented, for example, in software or hardware or in a software-hardware hybrid, for example, in a processing station (80), as illustrated by the schematic representation of FIG. 2.

What is claimed is:

1. A method for validating a simulation of a technical system, comprising:
computing a specified validation metric, in each case, for combinations of measurement series obtained on the system and results of the simulation corresponding to the measurement series; and
validating the simulation based on the specified validation metrics.

2. The method as recited in claim 1, wherein the system is an embedded system, and a functional reliability of the system is checked by the simulation.

3. The method as recited in claim 1, wherein: (i) the system is adapted for controlling a vehicle autonomously, or (ii) the system is adapted for controlling a manufacturing process.

4. The method as recited in claim 1, wherein: (i) the validation metrics are represented as a confidence interval, or (ii) the validation metrics are represented as a cumulative distribution function.

5. The method as recited in claim 1, wherein: (i) the specified validation metrics are a squared deviation from the mean value, or (ii) the respective validation metrics correspond to ISO/TS 18571:2014.

6. The method as recited in claim 1, wherein the validating of the simulation includes comparing the validation metrics with a predetermined threshold value.

7. The method as recited in claim 6, wherein the comparison is carried out automatically, and, as a function of the comparison, an error is recognized from case to case, or a warning is issued.

8. A non-transitory machine-readable storage medium on which is stored a computer program for validating a simulation of a technical system, the computer program, when executed by a computer, causing the computer to perform:
computing a specified validation metric, in each case, for combinations of measurement series obtained on the system and results of the simulation corresponding to the measurement series; and
validating the simulation based on the specified validation metrics.

9. A device configured to validate a simulation of a technical system, the device configured to:
compute a specified validation metric, in each case, for combinations of measurement series obtained on the system and results of the simulation corresponding to the measurement series; and
validate the simulation based on the specified validation metrics.
